(19) United States
(12) Patent Application Publication
(10) Pub. No.: US 2013/0118405 A1
(43) Pub. Date: May 16, 2013

(54) FLUID COOLED SHOWERHEAD WITH POST INJECTION MIXING

(71) Applicants: Henry Ho, San Jose, CA (US); Yong Jiang, Shanghai (CN)

(72) Inventors: Henry Ho, San Jose, CA (US); Yong Jiang, Shanghai (CN)

(21) Appl. No.: 13/337,247

(22) Filed: Dec. 26, 2011

(30) Foreign Application Priority Data
Nov. 10, 2011 (CN) 201110355292.7

(51) Int. Cl. C23C 16/455; B23P 17/04; B05B 7/08

(52) U.S. Cl. 118/715; 118/724; 239/549; 29/428

(57) ABSTRACT

A showerhead that injects two process gases into the processing chamber via separate sets of holes. The showerhead is constructed of upper plate and lower plate. Upper plate has a first set of holes. The lower plate has two sets of holes: one set is aligned with the holes in the upper plate, while the second set has no corresponding holes in the upper plate. Both sets of holes in the lower plate are made to have two different diameters: a larger diameter extending from the top surface of the lower plate, while a smaller diameter extends from the bottom surface and meets with the larger diameter. A set of pipes are inserted through the holes in the upper plate and the corresponding holes in the lower plate, and are sealingly brazed to both plates. Cooling channels may be provided in the lower plate.

### RELATED APPLICATION

This application claims priority from Chinese Patent Application Serial No. 201110355292.7, which was filed on Nov. 10, 2011, the entire disclosure of which is incorporated herein by reference.

### BACKGROUND

1. Field of the Application

This application is in the field of gas injection into processing chambers, especially for applications requiring showerheads with active cooling and post-injection mixing.

2. Related Art

Various processing chambers are known in the art and are used for fabrication of semiconductor devices, flat panels, solar cells, etc. An example of such chambers include chemical vapor deposition (CVD), plasma enhanced chemical vapor deposition (PECVD), metal organic chemical vapor deposition (MOCVD), vapor phase epitaxy (VPE), etc. In various applications, it is required that the processing gases will not mix prior to injection into the processing chambers. Accordingly, various designs have been proposed for showerheads that maintain the processing gas separately until injection into the processing chamber. Additionally, in various applications it is also beneficial to actively cool the showerhead, and various designs have been proposed to actively cool the showerhead using fluids, such as water. For some examples of such designs the reader is invited to review U.S. Pat. Nos. 5,871,586 and U.S. Publications 2010/0170438 and 2011/0052833.

One problem of the prior art designs is the complexity and cost of manufacturing. Since the processing gases need to be kept separately, the showerhead needs to be made of several plates and conduits in a complex arrangement. Additionally, cooling channels are required to be robust and withstand thermal stresses without springing any leaks. This leads to intricate designs that increase the cost of the showerhead. Accordingly, what is needed in the art is a simplified design that is easier and cheaper to manufacture, yet maintains the gas separation and fluid cooling features.

### SUMMARY

The following summary is included in order to provide a basic understanding of some aspects and features of the disclosure. This summary is not an extensive overview of the invention and as such it is not intended to particularly identify key or critical elements of the invention or to delineate the scope of the invention. Its sole purpose is to present some concepts of the invention in a simplified form as a prelude to the more detailed description that is presented below.

Embodiments of the invention enable simplified fabrication of a showerhead that can be used in various processing chambers, such as CVD, PECVD, MOCVD, VPE, etc., especially in applications where separate gas delivery and active cooling are required. Embodiments of the invention provide showerheads that have fewer parts and are more robust yet cheaper to manufacture.

Embodiments of the invention provide a showerhead that injects two process gases into the processing chamber via separate sets of holes. The showerhead is constructed of two plates: an upper plate and a lower plate. The upper plate has a first set of holes of a given diameter. The lower plate has two sets of holes: one set of holes is aligned with the set of holes in the upper plate, while the second set has no corresponding holes in the upper plate. Both sets of holes in the lower plate are made to have two different diameters: a larger diameter extending from the top surface of the lower plate, but not reaching the bottom surface, while a smaller diameter extends from the bottom surface and meets with the larger diameter. A set of pipes are inserted through the holes in the upper plate and the corresponding holes in the lower plate, and are sealingly brazed to both plates. Cooling channels may be provided in the lower plate for circulating cooling fluid therein.

According to disclosed aspects, a method for fabricating a showerhead is provided, comprising: fabricating an upper plate and drilling a first set of holes of a first diameter in the upper plate; fabricating a lower plate and drilling a second set of holes in the lower plate, each hole of the second set corresponding to one hole from the first set, such that all of the holes of the second set can be aligned with all of the holes of the first set, and further drilling a third set of holes in the lower plate, wherein each of the holes of the third set are fabricated by drilling gas entry holes of diameter matching the first diameter from an upper surface of the lower plate to a prescribed depth shorter than the thickness of the lower plate, and drilling gas exit holes of a second diameter, smaller than the first diameter, from bottom surface of the lower plate to a depth so as to fluidly meet the gas entry holes; and, affixing a plurality of conduits to the holes of the first set and the gas entry holes. The method may further include fabricating cooling channels in the lower plate.

According to further disclosed aspects, a processing chamber is provided, comprising a chamber enclosure having a ceiling, sidewall, and bottom; a substrate support situated to face the ceiling and defining a processing space; a showerhead assembly provided below the ceiling, the showerhead assembly comprising: an upper plate affixed below the ceiling and forming with the ceiling a sealed first gas distribution compartment, the upper plate having a first set of holes; a lower plate having a bottom surface exposed to the processing space and an upper surface forming with the upper plate a sealed second gas distribution compartment, the lower plate having a second set of holes aligned with the first set of holes and further having a third set of holes forming a path for delivering the second gas from the second gas distribution compartment to the processing space; and a plurality of pipes, each inserted and sealingly affixed to one hole of the first set of holes and a corresponding hole of the second set of holes, thereby forming a path for delivering the first gas from the first gas distribution compartment to the processing space.

According to yet other aspects, a showerhead assembly for separately delivering a first gas and a second gas into a processing chamber is provided, comprising: an upper plate having a first set of holes of a first diameter; a lower plate having a second set of holes, each hole of the second set corresponding to one hole from the first set, such that all of the holes of the second set can be aligned with all of the holes of the first set, and further having a third set of plurality of holes, wherein each of the holes of the second set and third set has a varying diameter along its length such that each hole's gas entry diameter is larger than the hole's gas exit diameter; and, a plurality of conduits inserted in and sealingly affixed to the holes of the first and second set.

### BRIEF DESCRIPTION OF THE DRAWINGS

Other aspects and features of the invention would be apparent from the detailed description, which is made with reference to the following drawings. It should be appreciated that the detailed description and the drawings provides various non-limiting examples of various embodiments of the invention, which is defined by the appended claims.

The accompanying drawings, which are incorporated in and constitute a part of this specification, exemplify various embodiments and, together with the description, serve to explain and illustrate principles of the invention. The drawings are intended to illustrate major features of the exemplary embodiments in a diagrammatic manner. The drawings are not intended to depict every feature of actual embodiments nor relative dimensions of the depicted elements and are, therefore, not drawn to scale.

FIG. 1 is a schematic of a processing chamber having a showerhead according to an embodiment of the invention.

FIG. 2A is a cross section of a showerhead according to an embodiment of the invention, which may be used in conjunction with the chamber of FIG. 1, while FIGS. 2B-2D are top and bottom elevations of the plates making the showerhead.

FIGS. 3A-3D illustrate another embodiment of a showerhead.

FIGS. 4A-4D illustrate yet another embodiment of a showerhead.

### DETAILED DESCRIPTION

Embodiments of the invention provide showerhead designs that are simpler to manufacture, require fewer parts, and are of lower cost. In general, various embodiments of the invention provide a showerhead made of only two plates, yet capable of separate injection of processing gas and liquid cooling of the lower plate.

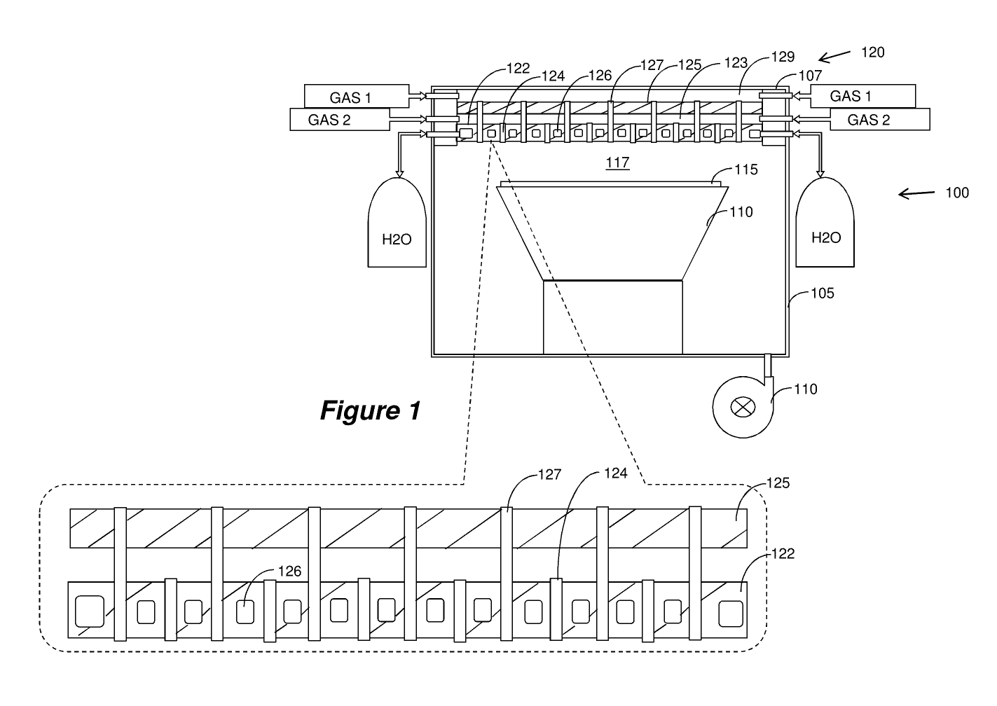

FIG. 1 illustrates an example of a processing chamber 100 utilizing a showerhead, generally indicated at 120, fabricated in accordance with embodiments of the invention. FIG. 1 illustrates the general structure of showerhead 120, while more detailed examples are provided in other Figures. In FIG. 1, chamber 100 includes an enclosure 105 that is evacuated by vacuum pump 110. A pedestal 11 supports one or more substrates 115 to be processed. The showerhead 120 is used to inject process gas 1 and process gas 2 into the chamber. The process gasses are kept separately until injection into the chamber, wherein they mix and react so as to provide the necessary processing on the substrate(s) 115.

In the particular example of FIG. 1, showerhead 120 is made of lower plate 122 and upper plate 125. The lower plate 122 faces the substrate(s) 115 to be processed, while the upper plate 125 is placed in an intermediate position between the lower plate 122 and the ceiling 107 of the enclosure 105. In this manner, the upper plate 125 forms distribution space 129 together with the ceiling 107, and upper plate 125 also forms distribution space 123 together with the lower plate 122. Gas 1 is delivered into the distribution space 129, and is distributed to conduits 127 to be injected into the processing areal 17 of processing chamber 100. Gas 2 is delivered to distribution space 123, and is distributed to conduits 124 to be injected into the processing area 117. Cooling fluid, such as chilled water, is delivered into cooling conduits 126 so as to cool the showerhead. As can be understood, a chilling system (not shown) for water or other fluid or liquid can be coupled to the cooling conduits 126 to condition the cooling fluid or liquid.

As shown in the callout of FIG. 1, the showerhead of this embodiment is fabricated of two plates: lower plate 122 and upper plate 125. Upper plate is rather simple to fabricate. It is generally a flat disk with a plurality of holes made therein, so that the first set of conduits 127, generally in the form of pipes, can be inserted or threaded therethrough. The first set of conduits 127 are made sufficiently long so that they can be inserted into holes in the lower plate 122 as well. Lower plate 122 is also in the form of a flat disk and has two sets of holes. The first set of holes is configured for threading the first set of conduits 127. The second set of holes is configured for threading a second set of conduits 124, each of which being shorter than conduits 127. In the particular embodiment of FIG. 1 the diameter of conduits 124 and 127 is the same, but the diameter can be set to be different as well. The lower plate 122 also incorporates cooling channels or conduits 126 that can be made in various configurations, some examples of which will be provided below. During fabrication, brazing material is applied to the conduits, the plates, or both. The first set of conduits 127 and the second set of conduits 124 are inserted through the respective holes in the lower and upper plates, and then the entire assembly is heated so as to braze the conduits and the plates together in a sealed manner.

It should be appreciated from the description of FIG. 1 that the showerhead maintains and delivers the two processing gases, gas 1 and gas 2, separately. Once the gases exit the showerhead into processing space 117 the gases can mix and cause the necessary chemical reaction for processing the substrate(s). Energy applicator, such as plasma, heat lamps, etc., may be used to provide the necessary energy to cause the two gases to react chemically.

As illustrated in FIG. 1, the processing gases and the cooling fluid are delivered to the showerhead from multiple locations. However, it should be understood that each of the gases can be delivered via a single corresponding port. Regarding the cooling fluid, improved cooling can be achieved by circulating the fluid through a chiller or other heat exchanging system. Therefore, it is advisable to provide at least one cooling fluid inlet and one cooling fluid outlet. When highly uniform temperature distribution are required, it may be advisable to use more than one cooling fluid inlet and more than one cooling fluid outlet.

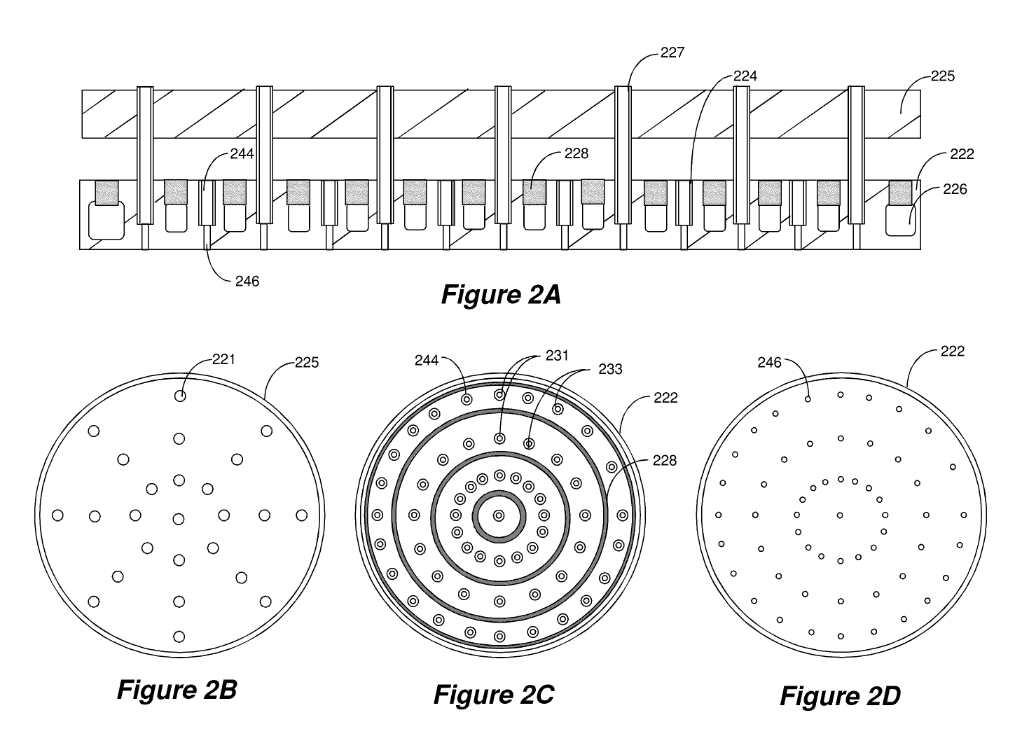

For many applications it is desired to have the gas exit the showerhead via many holes of very small diameter. However, making holes of small diameter is rather costly and sometimes requires exotic drilling technologies, such as laser drilling. Such exotic technologies have difficulty drilling holes of high aspect ratio (depth to diameter) and very small diameter. According to embodiments of the invention, the complexity and higher costs involved in drilling small holes are largely alleviated. An example of such a design is illustrated in FIGS. 2A-2D.

FIG. 2A illustrates a cross section of a showerhead according to an embodiment of the invention. The showerhead of FIG. 2A is made of two flat plates: lower plate 222 and upper plate 225. FIG. 2B is a top elevation illustrating the upper plate 225. As shown in FIG. 2B, plate 225 is rather simple to manufacture, as it is a flat disk having a set of holes 221 that may be of a diameter larger than that required for the gas injection into the processing chamber. That is, the holes 221 need not be of small diameter and may be chosen to be of a diameter that is rather easy to fabricate.

FIG. 2C is a top elevation of the lower plate 222. The plate incorporates two sets of hole: one set positioned to match the holes in the upper plate 225, and a second set of holes 233 positioned to deliver the second gas into the processing chamber. In this embodiment, the two sets of holes in the lower plate 222 are fabricated the same and each have a varying diameter along its axis. Each hole has a large diameter from the upper side, shown as 244, and a smaller diameter from the lower side, shown as 246. The small diameter 246 of the two sets of holes can be seen in the bottom elevation of the lower plate 222, illustrated in FIG. 2D. The smaller diameter 246 is selected so as to provide fine distribution of both gases into the processing chamber. However, rather than drilling these fine, small diameter, holes throughout the entire thickness of the lower plate 222, larger diameter holes 244 are drilled from the top surface of the plate 222 to a prescribed depth—not punching through the plate. Then, the small diameter holes 246 are drilled to punch through the lower surface of the lower plate 222, meeting the bottom surface of the larger diameter holes 244. This can be clearly seen in the cross section of FIG. 2A.

In this embodiment, cooling channels 226 are also fabricated in the lower plate 222. One method to simplify the fabrication of the cooling channels 226 is to simply cut the channels, for example, from the upper surface of the lower plate. Then, braze seals in the form of rings 228 to seal the channels 226, as shown in the cross section of FIG. 2A.

When the showerhead is assembled, long conduits 227 are inserted through the first set of holes 221 in the upper plate 225 and through the large diameter part 244 of holes 231 in the lower plate 222. Optionally, shorter conduits 224 are inserted through the large diameter part 244 of holes 233 of lower plate 222. Note that due to the varied diameter of the holes, the conduits are not exposed to the interior of the chamber, i.e., they do not extend to the bottom surface of the lower plate. The entire assembly can then be place in a furnace and heated to braze the conduits 227 and 224 and the ring seals 228. Note, however, that the shorter inserts can be omitted, such that the second set of holes 233 in the lower plate functions without inserts.

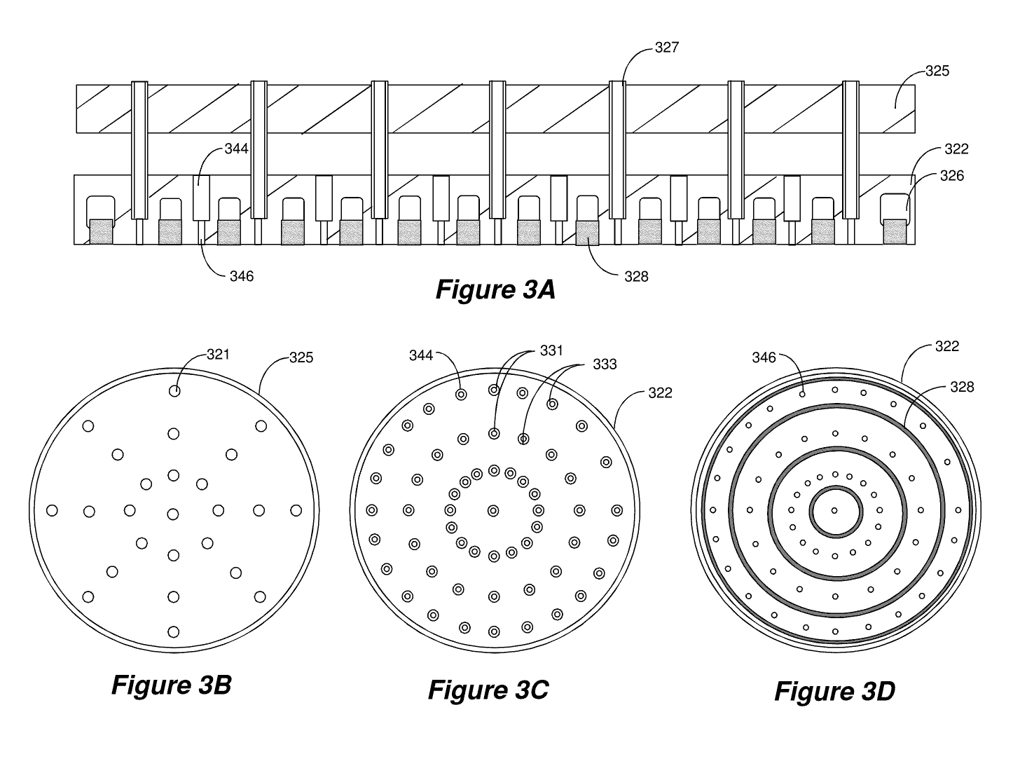

FIGS. 3A-3D illustrate another embodiment of the invention, wherein elements similar to that of FIGS. 2A-2D have the same reference numbers, except that they are in the 3xx series. The embodiment of FIGS. 3A-3D is similar to that of FIGS. 2A-2D, but illustrating two variations, either one of which can be implemented independently of the other. First, as can be seen, the ring seals 328 are provided from the bottom surface of lower plate 322. This means that the cooling channels 326 were machined from the bottom surface of the lower plate. Of course, other means can be used to fabricate the cooling channels. For example, if the plate is made of sintered ceramic, the channel can be made or molded in the green prior to firing the ceramic material.

FIGS. 3A-3D also illustrate the possibility of dispensing with the inserts or conduits in the set of holes 333 of the lower plate 322. The inserts 327 are still provided for the holes 331 that are aligned between the upper and lower plates, so that the first gas is delivered to the processing chamber and is not mixed with the second gas prior to injection. The brazing of these conduits 327 also holds the shower assembly together as one piece. Also, the inserts 327 extends only partially into the lower plate, such that they are not exposed to the processing space of the chamber. For example, if plasma is maintained in the processing space, the inserts 327 are not exposed to the plasma.

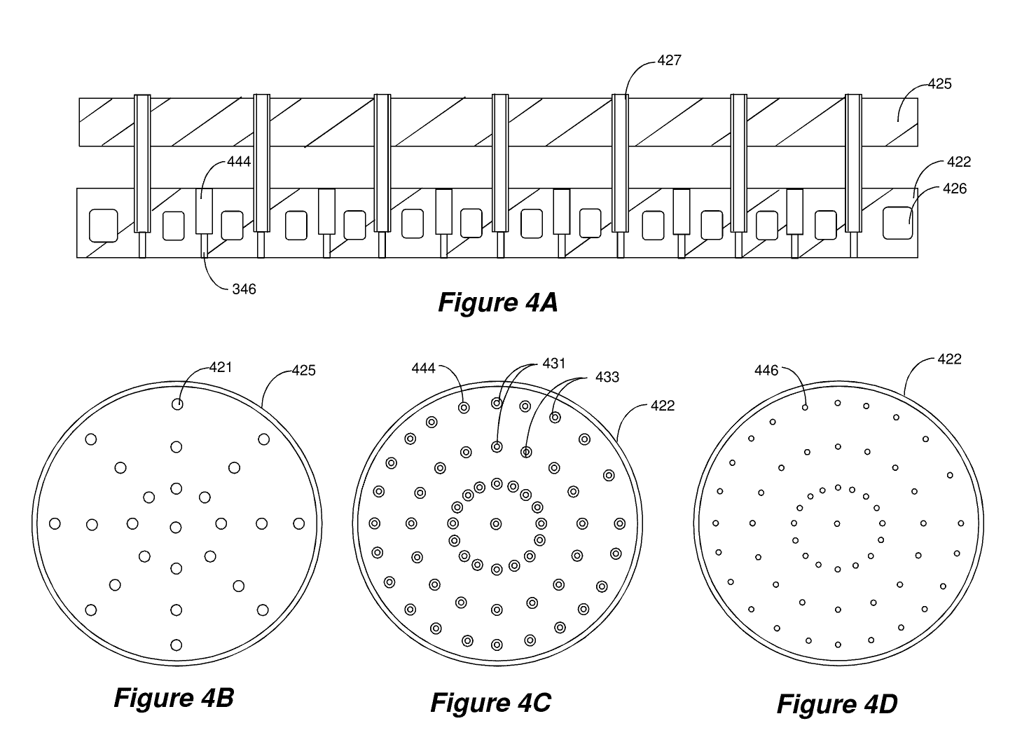

In the embodiments described above, the cooling channels are made simply and cheaply by using the ring seals. Of course, the cooling channels may be made to be internal to the lower plate without having the ring seals. While such an arrangement may be more complex to manufacture, it is safer from the view point of potential leaks. Such an embodiment is illustrated in FIG. 4A-4D, wherein elements similar to that of FIGS. 3A-3D have the same reference numbers, except in the 4xx series. The embodiment of FIGS. 4A-4D is similar to that of FIGS. 3A-3D, except that the cooling channels 426 are made internal to the lower plate 426.

As can be appreciated from the above description, embodiments of the invention enable a rather easy manufacturing since the entire showerhead assembly is made of only two plates. The top plate is simple with holes of large diameter that are easy and cheap to drill. The lower plate has holes that are for the large part of their depth of large diameter that is easy and cheap to drill. The small diameter holes required for the injection of gas into the processing chamber are made to a rather shallow depth, so as to ease the drilling of such holes. The insert conduits can be brazed to the two plates in one baking operation, to thereby attach the two plates in a sealed manner. The cooling channels may be made by either machining channels and sealing them with brazed seals, or making them internal to the lower plate. The resulting showerhead assembly maintains the two gases separate until injection into the processing chamber.

It should be understood that processes and techniques described herein are not inherently related to any particular apparatus and may be implemented by any suitable combination of components. Further, various types of general purpose devices may be used in accordance with the teachings described herein. It may also prove advantageous to construct specialized apparatus to perform the method steps described herein.

The terms and expressions used in describing the embodiments were employed for the purpose of description and not limitation, such that their use is not intended as excluding any equivalents or alternatives.

The present invention has been described in relation to particular examples, which are intended in all respects to be illustrative rather than restrictive. Those skilled in the art will appreciate that other implementations of the invention will be apparent to those skilled in the art from consideration of the specification and practice of the invention disclosed herein. It is intended that the specification and examples be considered as exemplary only, with a true scope and spirit of the invention being indicated by the following claims.

1. A showerhead assembly for separately delivering a first gas and a second gas into a processing chamber, comprising:
an upper plate having a first set of plurality of holes of a first diameter;
a lower plate having a second set of plurality of holes, each hole of the second set corresponding to one hole from the first set, such that all of the holes of the second set can be aligned with all of the holes of the first set, and further having a third set of plurality of holes, wherein each of the holes of the second set and third set has a varying diameter along its length such that each hole's gas entry diameter is larger than the hole's gas exit diameter; and,
a plurality of conduits inserted in and sealingly affixed to the holes of the first and second set.

2. The showerhead assembly of claim 1, wherein the gas entry diameter of the second set of holes equals the first diameter.

3. The showerhead assembly of claim 2, wherein the conduits are brazed to the holes of the first and second set.

4. The showerhead assembly of claim 3, further comprising a seconds set of conduits inserted in the third set of plurality of holes in the lower plate.

5. The showerhead assembly of claim 1, further comprising cooling channels in the lower plate.

6. The showerhead assembly of claim 5, further comprising ring seals affixed to the lower plate to seal the cooling channels.

7. The showerhead assembly of claim 1, wherein the plurality of conduits extend only partially through the lower plate.

8. A processing chamber wherein a first gas and a second gas are delivered separately into a processing chamber, comprising:
a chamber enclosure having a ceiling, sidewall, and bottom;
a substrate support situated to face the ceiling and define a processing space;
a showerhead assembly provided below the ceiling, the showerhead assembly comprising:
an upper plate affixed below the ceiling and forming with the ceiling a sealed first gas distribution compartment, the upper plate having a first set of holes;
a lower plate having a bottom surface exposed to the processing space and an upper surface forming with the upper plate a sealed second gas distribution compartment, the lower plate having a second set of holes aligned with the first set of holes and further having a third set of holes forming a path for delivering the second gas from the second gas distribution compartment to the processing space;
a plurality of pipes, each inserted and sealingly affixed to one hole of the first set of holes and a corresponding hole of the second set of holes, thereby forming a path for delivering the first gas from the first gas distribution compartment to the processing space.

9. The processing chamber according to claim 8, wherein the lower plate further comprises cooling channels for circulating cooling fluid therein.

10. The processing chamber according to claim 8, wherein each of the holes of the second set has a first diameter at an opening to the upper surface and a second diameter at an opening to the bottom surface and wherein the second diameter is smaller than the first diameter.

11. The processing chamber according to claim 10, wherein each hole of the first set has a diameter matching the first diameter.

12. The processing chamber according to claim 10, wherein each of the holes of the third set has a diameter at an opening to the bottom surface matching the second diameter.

13. The processing chamber according to claim 8, wherein the plurality of pipes are brazed to the upper and lower plates.

14. A method for fabricating a showerhead, comprising:
fabricating an upper plate and drilling a first set of plurality of holes of a first diameter in the upper plate;
fabricating a lower plate and drilling a second set of plurality of holes in the lower plate, each hole of the second set corresponding to one hole from the first set, such that all of the holes of the second set can be aligned with all of the holes of the first set, and further drilling a third set of plurality of holes in the lower plate, wherein each of the holes of the third set are fabricated by drilling gas entry holes of diameter matching the first diameter from an upper surface of the lower plate to a prescribed depth shorter than the thickness of the lower plate, and drilling gas exit holes of a second diameter, smaller than the first diameter, from bottom surface of the lower plate to a depth so as to fluidly meet the gas entry holes; and,
affixing a plurality of conduits to the holes of the first set and the gas entry holes.

15. The method of claim 14, wherein each of the holes of the second set are fabricated by drilling gas entry holes of one diameter from an upper surface of the lower plate to a prescribed depth shorter than the thickness of the lower plate, and drilling gas exit holes of a diameter matching the second diameter, smaller than the one diameter, from bottom surface of the lower plate to a depth so as to fluidly meet the gas entry holes.

16. The method of claim 15, wherein the one diameter matches the first diameter.

17. The method of claim 14, further comprising fabricating cooling channels in the lower plate.

18. The method of claim 17, further comprising affixing seals to the cooling channels.

19. The method of claim 14, wherein affixing a plurality of conduits comprises brazing the conduits.

20. A showerhead assembly for separately delivering a first gas and a second gas into a processing chamber, comprising:
an upper plate having a first set of plurality of holes of a first diameter;
a lower plate having a bottom surface configured to face and be exposed to a processing space and an upper surface configured to face the upper plate, and having a second set of plurality of holes, each hole of the second set corresponding to one hole from the first set, such that all of the holes of the second set can be aligned with all of the holes of the first set, and further having a third set of plurality of holes; and,
a plurality of conduits inserted in and sealingly affixed to the holes of the first and partially through the holes of the second set, such that the plurality of conduits do not reach the bottom surface of the lower plate.
